(19) United States
(12) Patent Application Publication
(10) Pub. No.: US 2013/0126342 A1
(43) Pub. Date: May 23, 2013

(54) IONIZATION DEVICE AND EVAPORATION DEPOSITION DEVICE USING THE IONIZATION DEVICE

(71) Applicants: TENG-TSUNG HUANG, Tu-Cheng (TW); LI-QUAN PENG, Shenzhen City (CN)

(72) Inventors: TENG-TSUNG HUANG, Tu-Cheng (TW); LI-QUAN PENG, Shenzhen City (CN)

(73) Assignees: HON HAI PRECISION INDUSTRY CO., LTD, Tu-Cheng (TW); HONG FU JIN PRECISION INDUSTRY (ShenZhen) CO., LTD, Shenzhen City (CN)

(21) Appl. No.: 13/407,384

(22) Filed: Feb. 28, 2012

(30) Foreign Application Priority Data
Nov. 21, 2011 (CN) 201110371072.3

(51) Int. Cl. C23C 14/46

(52) U.S. Cl. 204/298.04

(57) ABSTRACT

An ionization device used in an evaporation deposition device includes a main body, and an electron-beam system, a magnetic field generator all mounted to the main body. The main body includes a peripheral wall and a cavity enclosing by the peripheral wall. The electron-beam system includes an electric filament. The electric filament connects with a first power source. The electric filament and the main body connect with a direct current power source. The magnetic field generator includes a coil and a second power source connecting with the coil. An evaporation deposition device using the ionization device is also described.

### BACKGROUND

1. Technical Field

The present disclosure relates to ionization devices and evaporation deposition devices using the ionization devices, especially to an ionization device used for improving ionization ratio of evaporation source material, and an evaporation deposition device using the ionization device.

2. Description of Related Art

An evaporation deposition process evaporates source materials by electron-beam or electric filament in an vacuum environment. Evaporated source particles directly move to attach themselves to the target object (such as a substrate). The source particles convert into a solid film covering the target. However, during the evaporation deposition process, the evaporated particles are commonly insufficiently ionized. Accordingly, the particles are maintained at a low energy state with a low deposition rate, causing a poor bond between the film and the target substrate. Furthermore, the produced film is often uncontinuous.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an isometric view of one embodiment of an ionization device.

FIG. 2 is a cross-sectional view of the ionization device shown in FIG. 1 taken along line II-II.

FIG. 3 is an overhead view of the ionization device shown in FIG. 1.

FIG. 4 is a perspective view of an embodiment of an evaporation deposition device using the ionization device shown in FIG. 1.

### DETAILED DESCRIPTION

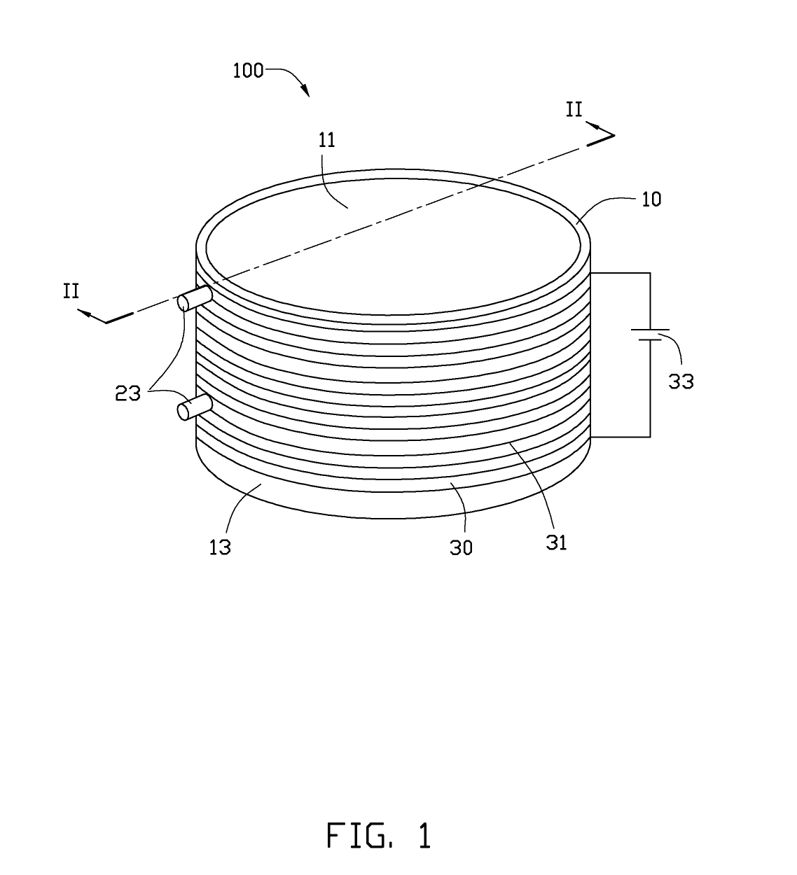

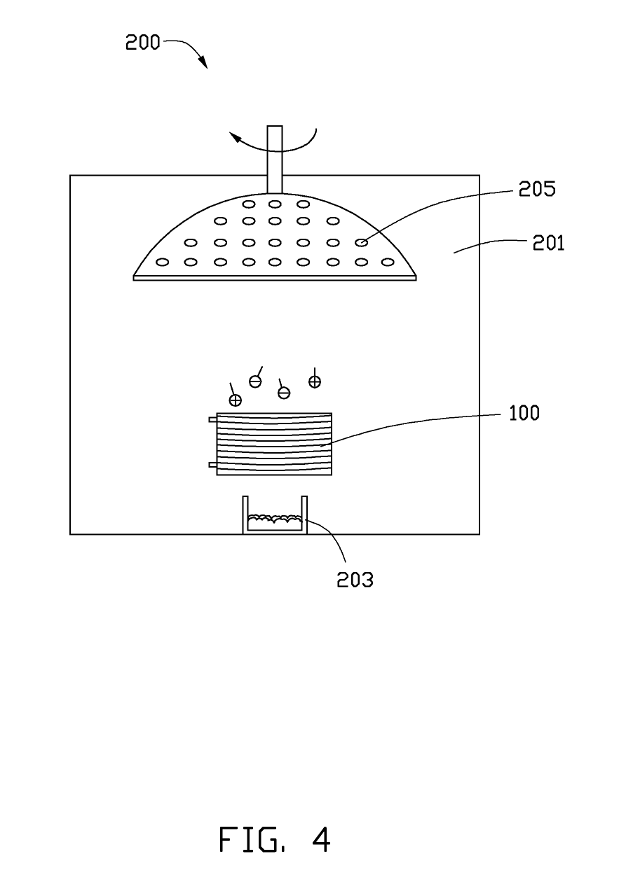

FIG. 1 shows an ionization device 100 in one embodiment being used in an evaporation deposition device 200 (referring to FIG. 4). The ionization device 100 can ionize gases, and source materials.

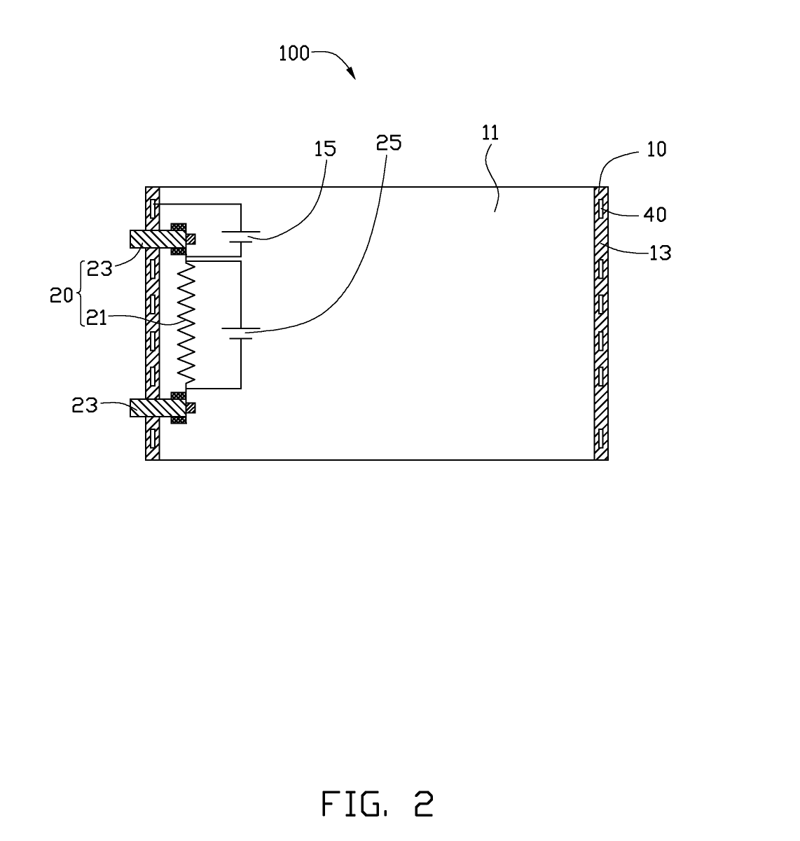

Also referring to FIG. 2, the ionization device 100 includes a main body 10, and a hot electron-beam system 20, a magnetic field generator 30, a cooling slot 40, all of which are mounted to the main body 10.

The main body 10 is a cylindrical structure having a open end and a lower open end. The main body 10 includes a peripheral wall 13 and a cavity 11 enclosed by the peripheral wall 13. The peripheral wall 13 has a thickness of about 1 centimeter (cm) to about 5 cm, and about 3 cm in the embodiment. The material of the main body 10 is metal or metal alloy having excellent electrical conductivity and thermal conductivity, such as aluminum, stainless steel, or copper. In the embodiment, the main body 10 is made of copper. The main body 10 has a diameter of about 1-3 times larger than the diameter of a crucible used for holding the source materials. In the embodiment, the main body 10 has a diameter of about 1.5 times larger than the diameter of the crucible.

Referring to FIG. 2, the electron-beam system 20 includes an electric filament 21, and two insulating blocks 23. The electric filament 21 is disposed inside the cavity 11 and is substantially parallel to the peripheral wall 13. The two insulating blocks 23 insert through the peripheral wall 13, and respectively connect with the two ends of the electric filament 21 to secure the electric filament 21 in the cavity 11. The electric filament 21 may be made of tungsten (W) or lanthanum boride (LaB). The insulating block 23 is made of ceramic. The electric filament 21 is connected with a first power source 25. When the first power source 25 is turned on, the electric filament 21 is electrified to generate heat and emit hot electrons in the cavity 11.

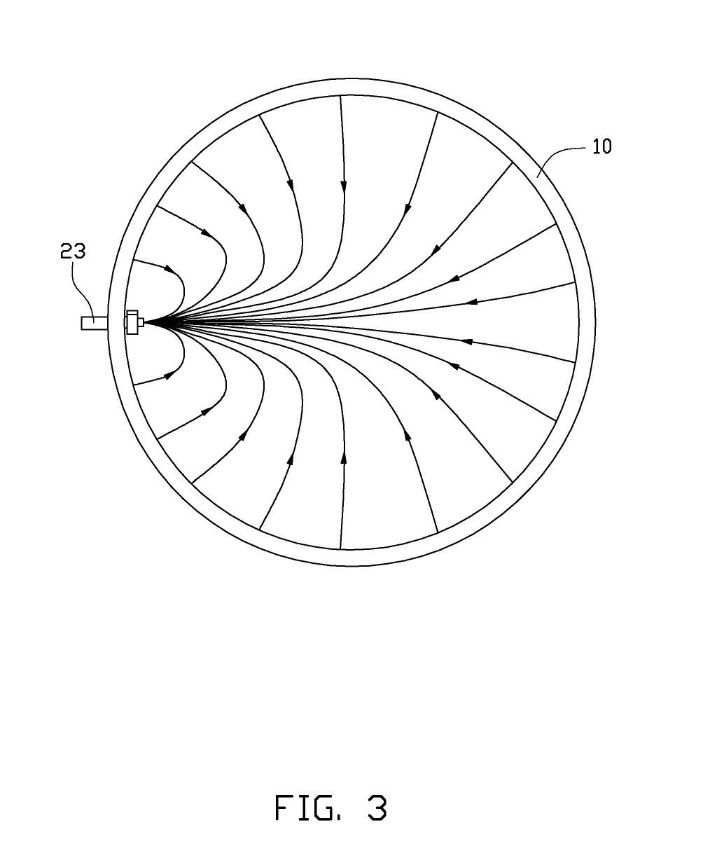

The main body 10 and the electric filament 21 are connected with a direct current power source 15, thus a direct voltage is generated between the main body 10 and the electric filament 21. The main body 10 connects with the anode of the direct current power source 15, and the electric filament 21 connects with the cathode of the direct current power source 15, so the electric potential of the main body 10 is higher than the electric potential of the electric filament 21. As such, an electric field which points from the main body 10 to the electric filament 21 is generated in the cavity 11 (see FIG. 3).

The magnetic field generator 30 includes a coil 31 and a second power source 33 connecting with the coil 31. The second power source 33 may be a direct current power source or an alternating current power source. The second power source 33 is used to adjust the current through the coil 31. When the second power source 33 is a direct current power source, the magnetic field generator 30 will generate a constant magnetic field along the longitudinal direction of the coil 31 and vertical to the electric field. When the second power source 33 is an alternating current power source, the magnetic field generator 30 will generate an alternating magnetic field along the longitudinal direction of the coil 31 and vertical to the electric field.

The cooling slot 40 is defined in the peripheral wall 13. The cooling agent flowing through the cooling slot 40 may be water or chlorofluorocarbons. The cooling slot 40 is connected with a group of pumps (not shown) which are used to drive the cooling agent to flow to cool the cooling slot 40.

In use, the ionization device 100 is disposed in a reaction chamber 201 of an evaporation deposition device 200 (referring to FIG. 4). A crucible 203 is disposed in the reaction chamber 201. The ionization device 100 is above the crucible 203. The crucible 203 is filled with source materials. The first power source 25 is turned on to allow the electric filament 21 to emit hot electrons. The direct current power source 15 is turned on to generate an electric potential difference between the main body 10 and the electric filament 21 and form an electric field pointing from the main body 10 to the electric filament 21. The second power source 33 is then turned on to generate a magnetic field. The hot electrons are first accelerated to move to the main body 10 along the reversed direction of the electric field. Under the action of the magnetic field, the hot electrons are then bound in the cavity 11 and circularly move in the cavity 11. The source materials are evaporated to particles and collide with the circularly moved hot electrons to be ionized and form electriferous ions with a high energy. The high energy electriferous ions accelerate depositing to the substrate 205 to form a continuous film having a strong bond with the substrate 205.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. An ionization device used in an evaporation deposition device, comprising:
a main body comprising a peripheral wall and a cavity enclosed by the peripheral wall;
an electron-beam system mounted to the main body, the electron-beam system comprising an electric filament connecting with a first power source, the electric filament and the main body connecting with a direct current power source; and
a magnetic field generator mounted to the main body, the magnetic field generator comprising a coil and a second power source connecting with the coil.

2. The ionization device as claimed in claim 1, wherein the main body is a cylindrical structure having an open end and a lower open end.

3. The ionization device as claimed in claim 1, wherein the peripheral wall has a thickness of about 1 cm to 5 cm.

4. The ionization device as claimed in claim 1, wherein the peripheral wall has a thickness of about 3 cm.

5. The ionization device as claimed in claim 1, wherein the main body is made of aluminum, stainless steel, or copper.

6. The ionization device as claimed in claim 1, wherein the electric filament is disposed inside in the cavity and parallels to the peripheral wall, when the first power source is turned on, the electric filament is electrified to generate heat and emit hot electrons in the cavity.

7. The ionization device as claimed in claim 6, wherein the electron-beam system further comprising two insulating blocks, the two insulating blocks insert through the peripheral wall and respectively connect with the two ends of the electric filament.

8. The ionization device as claimed in claim 1, wherein the electric filament is made of tungsten or lanthanum boride.

9. The ionization device as claimed in claim 7, wherein the insulating blocks are made of ceramic.

10. The ionization device as claimed in claim 1, wherein electric potential of the main body is higher than the electric potential of the electric filament, an electric field which points from the main body to the electric filament is formed in the cavity.

11. The ionization device as claimed in claim 10, wherein the second power source is a direct current power source or an alternating current power source.

12. The ionization device as claimed in claim 11, wherein when the second power source is a direct current power source, the magnetic field generator generates a constant magnetic field along the longitudinal direction of the coil and vertical to the electric field.

13. The ionization device as claimed in claim 11, wherein when the second power source is an alternating current power source, the magnetic field generator generates an alternating magnetic field along the longitudinal direction of the coil and vertical to the electric field.

14. The ionization device as claimed in claim 11, further comprising a cooling slot defined in the peripheral wall, the cooling slot is filled with a cooling agent.

15. An evaporation deposition device, comprising:
a reaction chamber;
a crucible disposed in the reaction chamber; and
an ionization device disposed above the crucible;
wherein the ionization device comprising:
a main body comprising a peripheral wall and a cavity enclosed by the peripheral wall;
an electron-beam system mounted to the main body, the electron-beam system comprising an electric filament connecting with a first power source, the electric filament and the main body connecting with a direct current power source; and
a magnetic field generator mounted to the main body, the magnetic field generator comprising a coil and a second power source connecting with the coil.

16. The evaporation deposition device as claimed in claim 15, wherein the main body has a diameter of about 1-3 times larger than the diameter of the crucible.

17. The evaporation deposition device as claimed in claim 15, wherein the main body has a diameter of about 1.5 times larger than the diameter of the crucible.

18. The evaporation deposition device as claimed in claim 15, wherein the electric filament is disposed inside in the cavity and parallels to the peripheral wall, when the first power source is turned on, the electric filament is electrified to generate heat and emit hot electrons in the cavity.

19. The evaporation deposition device as claimed in claim 15, wherein electric potential of the main body is higher than the electric potential of the electric filament, an electric field which points from the main body to the electric filament is formed in the cavity.

20. The evaporation deposition device as claimed in claim 19, wherein the second power source is a direct current power source or an alternating current power source, when the second power source is a direct current power source, the magnetic field generator generates a constant magnetic field along the longitudinal direction of the coil and vertical to the electric field, when the second power source is an alternating current power source, the magnetic field generator generates an alternating magnetic field along the longitudinal direction of the coil and vertical to the electric field.
